(19) United States
(12) Patent Application Publication
(10) Pub. No.: US 2025/0304822 A1
(43) Pub. Date: Oct. 2, 2025

(54) SLURRY COMPOSITION FOR CHEMICAL MECHANICAL POLISHING

(71) Applicant: KCTECH CO., LTD., Gyeonggi-do (KR)

(72) Inventors: Ji Hye KIM, Seoul (KR); Jae Ik LEE, Gyeonggi-do (KR); Bo Hyeok CHOI, Gyeonggi-do (KR)

(73) Assignee: KCTECH CO., LTD., Gyeonggi-do (KR)

(21) Appl. No.: 19/074,482

(22) Filed: Mar. 10, 2025

(30) Foreign Application Priority Data
Mar. 29, 2024 (KR) 10-2024-0043548

(51) Int. Cl. C09G 1/02; C09K 3/14; C23F 1/18; H01L 21/3105; H01L 21/321

(52) U.S. Cl. CPC C09G 1/02; C09K 3/1409; C23F 1/18; H01L 21/31053; H01L 21/3212

(57) ABSTRACT

Provided is a slurry composition for chemical mechanical polishing (CMP) including two types of colloidal silica abrasive particles, a pH buffer, and a pH adjuster, in which the two types of colloidal silica abrasive particles include first colloidal silica abrasive particles having a neutral charge and second colloidal silica abrasive particles having a negative charge.

### CROSS-REFERENCE TO RELATED APPLICATION

This application claims the benefit of Korean Patent Application No. 10-2024-0043548 filed on Mar. 29, 2024, in the Korean Intellectual Property Office, the entire disclosure of which is incorporated herein by reference for all purposes.

### BACKGROUND

### 1. Field of the Invention

One or more embodiments relate to a slurry composition for chemical mechanical polishing (CMP).

### 2. Description of the Related Art

As semiconductor devices become more diverse and highly integrated, finer pattern forming technologies are being used, and as a result, surface structures of semiconductor devices become more complicated and steps of surface films become larger. A chemical mechanical polishing (CMP) process is used as a planarization technology to remove steps in a specific film formed on a substrate in the manufacture of semiconductor devices. In the CMP process, a wafer to be flattened is placed on a rotating plate, a surface of the wafer is brought into contact with a pad of a polishing machine, and then the rotating plate and the pad of the polishing machine are rotated while supplying a slurry composition to perform the polishing process. That is, the slurry composition flows between a wafer surface and the pad, and the wafer surface is polished by mechanical friction between abrasive particles in the slurry composition and surface protrusions of the pad, and at the same time, chemical removal is performed by a chemical reaction between chemical components in the slurry composition and the wafer surface. In general, there are various types of slurry compositions depending on the type and characteristics of a target to be removed. Currently, there are a wide variety of slurries that selectively remove specific polishing films, but since existing polishing compositions use single particles, there has been a problem in that it is difficult to secure polishing rates for various film types, including a polysilicon film, an oxide film, a nitride film, and a copper film with a low solid content.

### SUMMARY

Embodiments provide a slurry composition for chemical mechanical polishing (CMP) capable of simultaneously securing polishing rates for various film types including a polysilicon film, an oxide film, a nitride film, and a copper film with a low solid content.

However, technical goals to be achieved are not limited to those described above, and other goals not mentioned above can be clearly understood by one of ordinary skill in the art from the following description.

According to an aspect, there is provided a slurry composition for CMP including two types of colloidal silica abrasive particles, a pH buffer, and a pH adjuster, wherein the two types of colloidal silica abrasive particles include first colloidal silica abrasive particles having a neutral charge and second colloidal silica abrasive particles having a negative charge.

Additional aspects of embodiments will be set forth in part in the description which follows and, in part, will be apparent from the description, or may be learned by practice of the disclosure.

According to embodiments, the slurry composition for CMP has the effect of simultaneously securing polishing rates for a silicon oxide film and a silicon nitride film even with a low solid content by applying polishing agents having two different charges simultaneously.

It should be understood that the effects of the present disclosure are not limited to the above-described effects, but are construed as including all effects that can be inferred from the configurations and features described in the following description or claims of the present disclosure.

### DETAILED DESCRIPTION

Hereinafter, embodiments will be described in detail. However, various alterations and modifications may be made to the embodiments. Here, the embodiments are not construed as limited to the disclosure. The embodiments should be understood to include all changes, equivalents, and replacements within the idea and the technical scope of the disclosure.

The terminology used herein is for the purpose of describing particular embodiments only and is not to be limiting of the embodiments. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

In addition, the description of embodiments, detailed description of well-known related structures or functions will be omitted when it is deemed that such description will cause ambiguous interpretation of the present disclosure.

In addition, the terms first, second, A, B, (a), and (b) may be used to describe constituent elements of the embodiments. These terms are used only for the purpose of discriminating one component from another component, and the nature, the sequences, or the orders of the components are not limited by the terms.

A component, which has the same common function as a component included in any one embodiment, will be described by using the same name in other embodiments. Unless disclosed to the contrary, the description of any one embodiment may be applied to other embodiments, and the specific description of the repeated configuration will be omitted.

It will be understood that when a certain part “includes” a certain component, the part does not exclude another component but may further include another component.

One aspect of the present disclosure provides a slurry composition for chemical mechanical polishing (CMP) including two types of colloidal silica abrasive particles, a pH buffer, and a pH adjuster, wherein the two types of colloidal silica abrasive particles include first colloidal silica abrasive particles having a neutral charge and second colloidal silica abrasive particles having a negative charge.

When only colloidal silica abrasive particles having a neutral charge are used, a high oxide film polishing rate may be secured, but a nitride film polishing rate is reduced. When only colloidal silica abrasive particles having a negative charge are used, a high nitride film polishing rate may be secured, but a sufficient oxide film polishing rate may not be secured. However, the slurry composition for CMP according to the present disclosure includes the two types of colloidal silica abrasive particles having different charges as the abrasive particles, and therefore, it is advantageous that polishing rates for a silicon oxide film and a silicon nitride film may be secured simultaneously even with a low solid content.

According to an embodiment, the two types of colloidal silica abrasive particles may be included in an amount of 0.01 wt % to 10 wt %, desirably 0.01 wt % to 5 wt %, and more desirably 1 wt % to 3 wt % with respect to a total weight of the slurry composition. When the content of the two types of colloidal silica abrasive particles is less than the lower limit, sufficient polishing rates for the silicon oxide film and the silicon nitride film may not be secured, and when the content thereof exceeds the upper limit, scratches generated due to the abrasive particles may increase. The slurry composition according to the present disclosure has the advantage of being able to secure sufficient polishing rates for the silicon oxide film and the silicon nitride film while limiting the solid content to a predetermined level or less, particularly to a low level of 3 wt % or less, as described above.

The slurry composition for CMP according to the present disclosure may adjust the polishing rates for the silicon oxide film and the silicon nitride film by adjusting a weight ratio of the two types of colloidal silica abrasive particles. According to an embodiment, the weight ratio of the first colloidal silica abrasive particles to the second colloidal silica abrasive particles may be 3:17 to 17:3, desirably 2:8 to 8:2, or 3:7 to 7:3. Regarding the weight ratio of the first colloidal silica abrasive particles to the second colloidal silica abrasive particles, when the proportion of the first colloidal silica abrasive particles is less than the above range, the polishing rate for an oxide film may not be sufficiently secured, and when the proportion of the second colloidal silica abrasive particles is less than the above range, the polishing rate for a nitride film may not be sufficiently secured.

According to an embodiment, primary particles of the two types of colloidal silica abrasive particles may have a diameter of 15 nanometers (nm) to 90 nm, desirably 20 nm to 70 nm, more desirably 25 nm to 55 nm, and secondary particles of the two types of colloidal silica abrasive particles may have a diameter of 40 nm to 150 nm, desirably 50 nm to 130 nm, and more desirably 55 nm to 110 nm. When the particle size of the colloidal silica abrasive particles exceeds the upper limit, surface scratch defects may increase, and when the particle size thereof is less than the lower limit, a sufficient polishing rate for a nitride film may not be secured.

The pH buffer is used to prevent a rapid change in a pH that occurs when preparing a composition by mixing abrasive particles, a pH adjuster, and the like, and the pH buffer according to an embodiment may contain organic acid, an amine compound, or both. Specifically, the pH buffer may contain at least one selected from the group consisting of picolinic acid, nicotinic acid, isonicotinic acid, fusaric acid, dinicotinic acid, dipiconilic acid, lutidinic acid, quinolic acid, glutamic acid, alanine, glycine, cystine, histidine, asparagine, guanidine, hydrazine, ethylenediamine, formic acid, acetic acid, benzoic acid, oxalic acid, succinic acid, malic acid, maleic acid, malonic acid, citric acid, lactic acid, tricarballyic acid, tartaric acid, aspartic acid, glutaric acid, adipic acid, suberic acid, fumaric acid, phthalic acid, pyridinecarboxylic acid, and salts thereof, and desirably at least one selected from the group consisting of picolinic acid and glycine. When picolinic acid or glycine is used as the pH buffer, there is an advantage of being able to secure dispersion stability.

According to an embodiment, the pH buffer may be included in an amount of 0.01 wt % to 2 wt %, and desirably 0.01 wt % to 1 wt % with respect to the total weight of the slurry composition.

The pH adjuster is a substance added to adjust the pH of the slurry composition to a desired pH, and may be used in an appropriate amount within a range that may achieve the desired pH. The pH adjuster may use an acidic substance, a basic substance, or both, and the acidic substance according to an embodiment may contain one or more selected from the group consisting of nitric acid, hydrochloric acid, phosphoric acid, sulfuric acid, hydrofluoric acid, hydrobromic acid, iodic acid, formic acid, malonic acid, maleic acid, oxalic acid, acetic acid, adipic acid, citric acid, acetic acid, propionic acid, fumaric acid, lactic acid, salicylic acid, pimelic acid, benzoic acid, succinic acid, phthalic acid, butyric acid, glutaric acid, glutamic acid, glycolic acid, lactic acid, aspartic acid, tartaric acid, and salts thereof, and the basic substance may contain one or more selected from the group consisting of ammonium methyl propanol (AMP), tetramethyl ammonium hydroxide (TMAH), ammonium hydroxide, potassium hydroxide, sodium hydroxide, magnesium hydroxide, rubidium hydroxide, cesium hydroxide, sodium bicarbonate, sodium carbonate, imidazole, and salts thereof.

According to an embodiment, the pH of the slurry composition according to the present disclosure may be 1 to 4, desirably equal to or more than 1 and less than 3, or 1 to 2. When the pH of the slurry composition is less than the lower limit, toxicity of the slurry composition may increase, and when the pH thereof exceeds the upper limit, polishing selectivity of the nitride film to the oxide film desired in the present disclosure may not be achieved.

A polishing target film of the slurry composition for CMP according to the present disclosure may contain a silicon oxide film and a silicon nitride film, or may contain a polysilicon film, a silicon oxide film, a silicon nitride film, and a copper film, and may be a multi-film material including, for example, a through-silicon via (TSV). In this case, a polishing rate for the polysilicon film of the slurry composition may be 300 Å/min or more, a polishing rate for the silicon oxide film may be 300 Å/min or more, and a polishing rate for the silicon nitride film may be 600 Å/min or more. The slurry composition of the present disclosure applies colloidal silica particles having two charges simultaneously, and therefore, it has the effect of simultaneously securing the polishing rates for the silicon oxide film and the silicon nitride film even with a low solid content.

Hereinafter, the present disclosure will be described in more detail with reference to examples. The following examples are provided for the purpose of illustrating the present disclosure and are not intended to limit the scope of the present disclosure.

### EXAMPLES

### Preparation Example

According to Tables 1 and 2 below, compositions of Examples 1 to 8 and Comparative Examples 1 to 13 were prepared, each including 0.1 wt % of picolinic acid as the pH buffer, 0.035 wt % of nitric acid as the pH adjuster, and including the first colloidal silica particles having a neutral charge and/or the second colloidal silica particles having a negative charge as shown in Table 1 below. A zeta potential value of the first colloidal silica was 0±5 mV when measured at the pH of 2, and a zeta potential value of the second colloidal silica was −40 mV to −20 mV when measured at the pH of 2.

TABLE 1

| | First colloidal silica | | Second colloidal silica | | | | |
|---|---|---|---|---|---|---|---|
| | particles | | particles | | | | |
| | Primary | Secondary | Primary | Secondary | | | |
| | particle | particle | particle | particle | Solid | Mixing | |
| | diameter | diameter | diameter | diameter | content | weight | |
| | (nm) | (nm) | (nm) | (nm) | (wt %) | ratio | pH |
| Example 1 | 30 | 70 | 30 | 60 | 2 | 2:8 | 2 |
| Example 2 | 30 | 70 | 30 | 60 | 2 | 5:5 | 2 |
| Example 3 | 30 | 70 | 30 | 60 | 2 | 8:2 | 2 |
| Example 4 | 50 | 100 | 30 | 60 | 2 | 2:8 | 2 |
| Example 5 | 50 | 100 | 30 | 60 | 2 | 5:5 | 2 |
| Example 6 | 50 | 100 | 30 | 60 | 2 | 8:2 | 2 |
| Example 7 | 30 | 70 | 30 | 70 | 2 | 5:5 | 2 |
| Example 8 | 30 | 70 | 50 | 100 | 2 | 5:5 | 2 |
| Comparative | 30 | 70 | — | — | 2 | 10:0 | 2 |
| Example 1 | | | | | | | |
| Comparative | 30 | 70 | 30 | 60 | 2 | 9:1 | 2 |
| Example 2 | | | | | | | |
| Comparative | 30 | 70 | 30 | 60 | 2 | 1:9 | 2 |
| Example 3 | | | | | | | |
| Comparative | — | — | 30 | 60 | 2 | 0:10 | 2 |
| Example 4 | | | | | | | |
| Comparative | 10 | 30 | — | — | 2 | 10:0 | 2 |
| Example 5 | | | | | | | |
| Comparative | 10 | 30 | 30 | 60 | 2 | 2:8 | 2 |
| Example 6 | | | | | | | |
| Comparative | 10 | 30 | 30 | 60 | 2 | 5:5 | 2 |
| Example 7 | | | | | | | |
| Comparative | 10 | 30 | 30 | 60 | 2 | 8:2 | 2 |
| Example 8 | | | | | | | |
| Comparative | 100 | 160 | — | — | 2 | 10:0 | 2 |
| Example 9 | | | | | | | |
| Comparative | 100 | 160 | 30 | 60 | 2 | 2:8 | 2 |
| Example 10 | | | | | | | |
| Comparative | 100 | 160 | 30 | 60 | 2 | 5:5 | 2 |
| Example 11 | | | | | | | |
| Comparative | 100 | 160 | 30 | 60 | 2 | 8:2 | 2 |
| Example 12 | | | | | | | |
| Comparative | 30 | 70 | 30 | 60 | 2 | 5:5 | 3 |
| Example 13 | | | | | | | |

### Experimental Example: Evaluation of Polishing Rate

Using the prepared compositions of the Examples 1 to 8 and Comparative Examples 1 to 13, the polishing rates were evaluated according to the evaluation conditions below, and the results thereof are shown in Table 2.

### Evaluation Conditions

Evaluation equipment: SP-01/K1000 (KCT)
Carrier rpm: 78
Platen rpm: 83
Wafer pressure: 2.0
R-ring pressure: 3.7
Slurry flow rate: 200 ml/min
Polishing pad: IC 1000

TABLE 2

| | Poly-Si | Oxide | Nitride | | | |
|---|---|---|---|---|---|---|
| | polishing | polishing | polishing | Evaluation | | |
| | rate | rate | rate | Poly | Oxide | Nitride |
| | (Å/min) | (Å/min) | (Å/min) | (300 Å≤) | (300 Å≤) | (500 Å≤) |
| Example 1 | 310 | 300 | 800 | ◯ | ◯ | ◯ |
| Example 2 | 310 | 340 | 700 | ◯ | ◯ | ◯ |
| Example 3 | 350 | 380 | 600 | ◯ | ◯ | ◯ |
| Example 4 | 320 | 300 | 760 | ◯ | ◯ | ◯ |
| Example 5 | 310 | 350 | 700 | ◯ | ◯ | ◯ |
| Example 6 | 380 | 420 | 540 | ◯ | ◯ | ◯ |
| Example 7 | 310 | 340 | 500 | ◯ | ◯ | ◯ |
| Example 8 | 330 | 320 | 550 | ◯ | ◯ | ◯ |
| Comparative | 350 | 420 | 120 | ◯ | ◯ | X |
| Example 1 | | | | | | |
| Comparative | 320 | 400 | 180 | ◯ | ◯ | X |
| Example 2 | | | | | | |
| Comparative | 380 | 150 | 820 | ◯ | X | ◯ |
| Example 3 | | | | | | |
| Comparative | 320 | 90 | 840 | ◯ | X | ◯ |
| Example 4 | | | | | | |
| Comparative | 350 | 60 | 40 | ◯ | X | X |
| Example 5 | | | | | | |
| Comparative | 340 | 40 | 730 | ◯ | X | ◯ |
| Example 6 | | | | | | |
| Comparative | 310 | 50 | 680 | ◯ | X | ◯ |
| Example 7 | | | | | | |
| Comparative | 300 | 60 | 540 | ◯ | X | ◯ |
| Example 8 | | | | | | |
| Comparative | 340 | 50 | 800 | ◯ | X | ◯ |
| Example 9 | | | | | | |
| Comparative | 300 | 110 | 750 | ◯ | X | ◯ |
| Example 10 | | | | | | |
| Comparative | 350 | 160 | 700 | ◯ | X | ◯ |
| Example 11 | | | | | | |
| Comparative | 310 | 220 | 510 | ◯ | X | ◯ |
| Example 12 | | | | | | |
| Comparative | 320 | 80 | 750 | ◯ | X | ◯ |
| Example 13 | | | | | | |

Referring to Table 2 above, even if the primary particle diameter and secondary particle diameter of the first colloidal silica and the second colloidal silica and the pH of the composition are limited to the ranges specified in the present disclosure, it may be confirmed that the compositions of Comparative Examples 1 to 4, in which the weight ratio of the first colloidal silica to the second colloidal silica is outside of 3:17 to 17:3, fail to secure the oxide film polishing rate and the nitride film polishing rate desired in the present disclosure. Particularly, it may be confirmed that, when the weight proportion of the second colloidal silica is less than the above range, a sufficient nitride film polishing rate is not achieved, and when the weight proportion of the first colloidal silica is less than the above range, a sufficient oxide film polishing rate is not secured.

In addition, referring to Comparative Examples 6 to 8 and 10 to 12, it may be confirmed that, even if the weight ratio of the first colloidal silica to the second colloidal silica satisfies the range of 3:17 to 17:3, a sufficient oxide film polishing rate is not secured when diameters of the primary particles and the secondary particles of the first colloidal silica are outside of 15 nm to 90 nm and 40 nm to 150 nm, respectively.

In addition, referring to Comparative Example 13, it may be confirmed that, even if the diameter of the colloidal silica particles and the weight ratio of the first colloidal silica particles to the second colloidal silica particles are both within the range of an embodiment of the present disclosure, a desired oxide film polishing rate is not achieved when the pH is 3.

Therefore, the slurry composition of the present disclosure has the effect of simultaneously securing the polishing rates for an oxide film and a nitride film while maintaining a poly-Si polishing rate at a predetermined level or higher.

While the embodiments are described, it will be apparent to one of ordinary skill in the art that various alterations and modifications in form and details may be made in these embodiments without departing from the spirit and scope of the claims and their equivalents. For example, suitable results may be achieved if the described techniques are performed in a different order, and/or if components in a described system, architecture, device, or circuit are combined in a different manner, or replaced or supplemented by other components or their equivalents.

Therefore, other implementations, other embodiments, and equivalents to the claims are also within the scope of the following claims.

What is claimed is:

1. A slurry composition for chemical mechanical polishing (CMP) comprising:
two types of colloidal silica abrasive particles;
a pH buffer; and
a pH adjuster,
wherein the two types of colloidal silica abrasive particles comprise first colloidal silica abrasive particles having a neutral charge and second colloidal silica abrasive particles having a negative charge.

2. The slurry composition of claim 1, wherein a weight ratio of the first colloidal silica abrasive particles to the second colloidal silica abrasive particles is 3:17 to 17:3.

3. The slurry composition of claim 1, wherein primary particles of the two types of colloidal silica abrasive particles has a diameter of 15 nanometers (nm) to 90 nm.

4. The slurry composition of claim 1, wherein secondary particles of the two types of colloidal silica abrasive particles has a diameter of 40 nm to 150 nm.

5. The slurry composition of claim 1, wherein the pH buffer comprises organic acid, an amine compound, or both.

6. The slurry composition of claim 5, wherein the pH buffer comprises at least one selected from the group consisting of picolinic acid, nicotinic acid, isonicotinic acid, fusaric acid, dinicotinic acid, dipiconilic acid, lutidinic acid, quinolic acid, glutamic acid, alanine, glycine, cystine, histidine, asparagine, guanidine, hydrazine, ethylenediamine, formic acid, acetic acid, benzoic acid, oxalic acid, succinic acid, malic acid, maleic acid, malonic acid, citric acid, lactic acid, tricarballyic acid, tartaric acid, aspartic acid, glutaric acid, adipic acid, suberic acid, fumaric acid, phthalic acid, pyridinecarboxylic acid, and salts thereof.

7. The slurry composition of claim 1, wherein
the pH adjuster comprises an acidic substance, a basic substance, or both,
the acidic substance comprises one or more selected from the group consisting of nitric acid, hydrochloric acid, phosphoric acid, sulfuric acid, hydrofluoric acid, hydrobromic acid, iodic acid, formic acid, malonic acid, maleic acid, oxalic acid, acetic acid, adipic acid, citric acid, acetic acid, propionic acid, fumaric acid, lactic acid, salicylic acid, pimelic acid, benzoic acid, succinic acid, phthalic acid, butyric acid, glutaric acid, glutamic acid, glycolic acid, lactic acid, aspartic acid, tartaric acid, and salts thereof, and
the basic substance comprises one or more selected from the group consisting of ammonium methyl propanol (AMP), tetramethyl ammonium hydroxide (TMAH), ammonium hydroxide, potassium hydroxide, sodium hydroxide, magnesium hydroxide, rubidium hydroxide, cesium hydroxide, sodium bicarbonate, sodium carbonate, imidazole, and salts thereof.

8. The slurry composition of claim 1, wherein the two types of colloidal silica abrasive particles are included in an amount of 0.01 wt % to 10 wt % with respect to a total weight of the slurry composition.

9. The slurry composition of claim 1, wherein the pH buffer is included in an amount of 0.01 wt % to 2 wt % with respect to a total weight of the slurry composition.

10. The slurry composition of claim 1, wherein a pH is equal to or more than 1 and less than 3.

11. The slurry composition of claim 1, wherein
a polishing target film of the slurry composition comprises a silicon oxide film and a silicon nitride film,
a polishing rate for the silicon oxide film is 300 Å/min or more, and
a polishing rate for the silicon nitride film is 600 Å/min or more.

12. The slurry composition of claim 1, wherein a polishing target film of the slurry composition comprises copper.
